(19) United States
(12) Patent Application Publication
(10) Pub. No.: US 2013/0112454 A1
(43) Pub. Date: May 9, 2013

(54) ELECTRONIC DEVICE HOUSING

(71) Applicants: XUE-FENG WAN, Shenzhen City (CN); BAO-GANG ZHAO, Shenzhen City (CN); PING LI, Shenzhen City (CN); YUAN-MING WANG, Shenzhen City (CN)

(72) Inventors: XUE-FENG WAN, Shenzhen City (CN); BAO-GANG ZHAO, Shenzhen City (CN); PING LI, Shenzhen City (CN); YUAN-MING WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/541,793

(22) Filed: Jul. 5, 2012

(30) Foreign Application Priority Data
Nov. 9, 2011 (CN) 201110351696.9

(51) Int. Cl. H05K 5/00

(52) U.S. Cl. 174/50

(57) ABSTRACT

A housing of an electronic device comprises an upper cover and a front panel secured to the upper cover. The upper cover includes a locking portion. The front panel includes a limiting portion corresponding to the locking portion. The locking portion includes at least one locking plate. The limiting portion defines at least one recess corresponding to the at least one locking plate. The at least one locking plate is locked to the recess for preventing the upper cover from deforming and moving to separate from the front panel.

### BACKGROUND

1. Technical Field

The present disclosure relates to housing of electronic devices.

2. Description of Related Art

A housing of electronic devices, such as DVD players, includes a bottom cover, an upper cover covering the bottom cover to form a casing with an opening, and a front panel arranged on the opening to form a closed space with the bottom cover and the upper cover. The upper cover includes a top plate. At least one blocking plate extended from the edge of the top plate. Each of the blocking plates includes a latching hole. At least one bulge is disposed at the sidewall of the front panel corresponding to the at least one blocking plate. The bulge is received in and locked to the latching hole, such that the front panel is secured to the upper cover. However, the upper cover is easily deformed causing the bulge to separate from the latching hole during use which results in the upper cover disengaging from the front panel and a gap forming between the upper cover and the front panel.

Therefore, there is room for improvement in the art.

### BRIEF DESCRIPTION OF THE FIGURE

The components of the drawings are not necessarily drawn to scale, the emphasis instead being placed upon clearly illustrating the principles of the embodiment of an electronic device. Moreover, in the drawings, like reference numerals designate corresponding parts throughout several views.

FIG. 1 is a schematic view of a housing, according to an embodiment.

FIG. 2 is a partially disassembled view of the housing of FIG. 1 from another aspect.

FIG. 3 is a partially enlarged view of one part of the housing of FIG. 2 from another aspect.

FIG. 4 is an enlarged view of section IV of FIG. 3.

FIG. 5 is an enlarged view of section V of FIG. 2.

FIG. 6 is a cross-section view taken along a line VI-VI of FIG. 1.

### DETAILED DESCRIPTION

Embodiments of the present disclosure will now be described in detail with reference to the drawings.

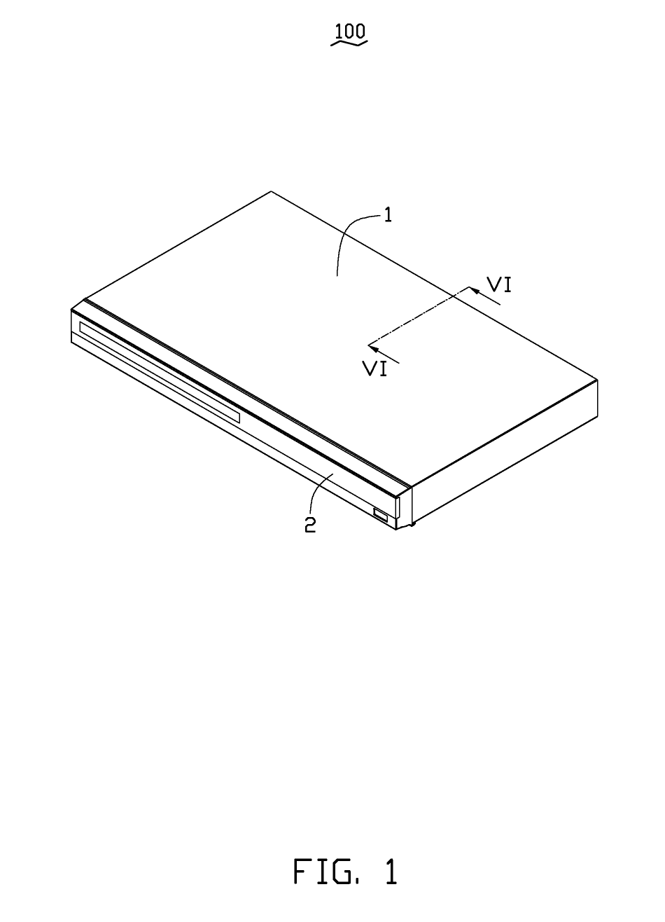

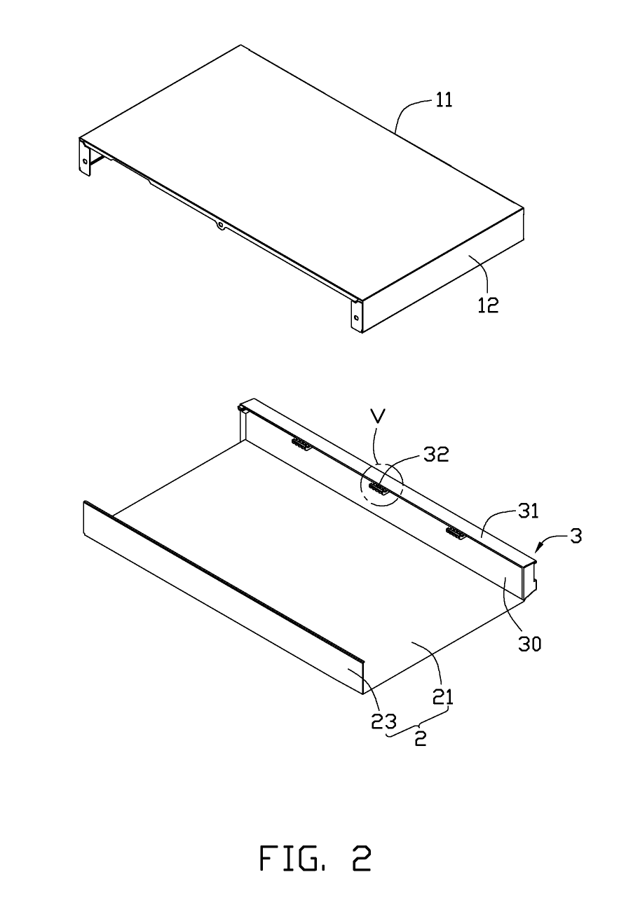

FIGS. 1 and 2, show a housing of an electronic device 100 of the embodiment. The electronic device 100 includes an upper cover 1 and a lower cover 2 covering the upper cover 1. In the embodiment, the bottom cover 2 cooperates with the upper cover 1 to form a closed space (not labeled). In the embodiment, the electronic device 100 is a portable DVD player.

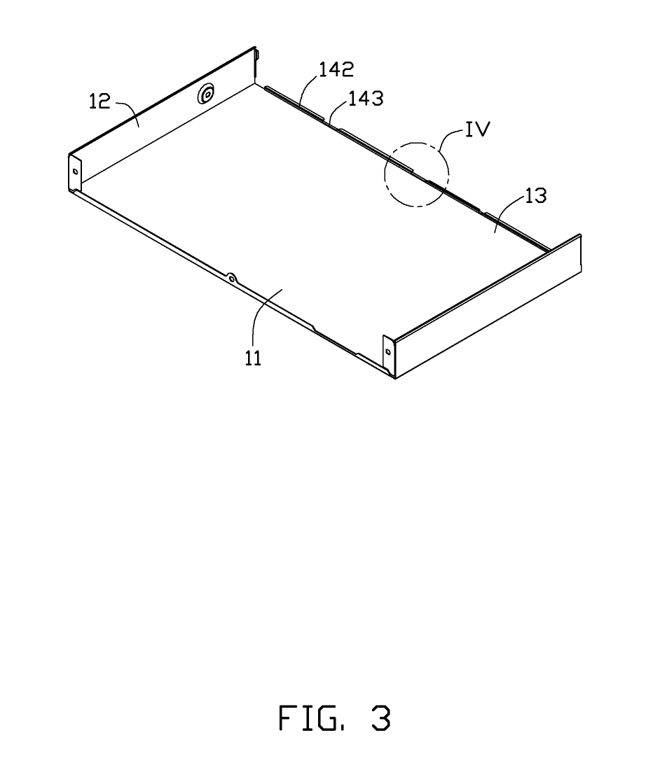

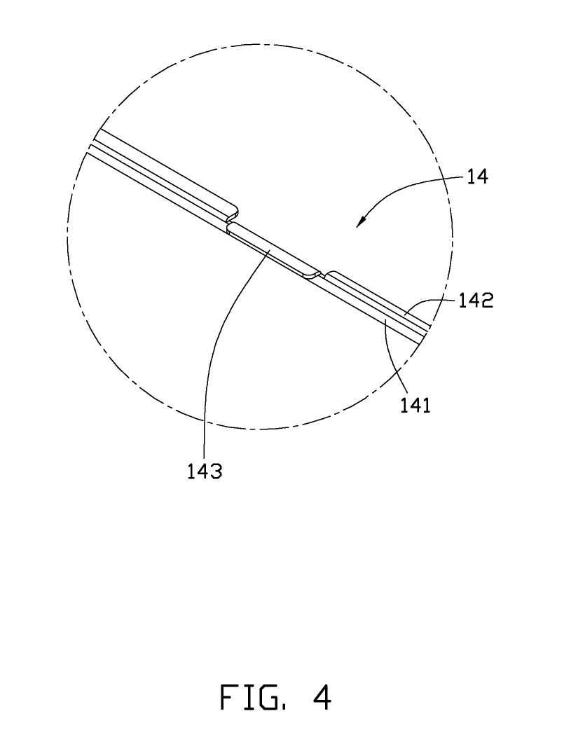

FIGS. 3-4, the upper cover 1 of the embodiment. The upper cover 1 includes a top plate 11, two sidewalls 12, a front edge 13, and a locking portion 14. The top plate 11 is substantially rectangular shaped. The sidewalls 12 perpendicularly extend from opposite edges of the top plate 11.

The locking portion 14 is secured to the front edge 13 interconnecting ends of the sidewalls 12. The locking portion 14 includes at least one blocking plate 141, at least one supporting plate 142, and at least one locking plate 143. The blocking plate 141 is perpendicularly extended from the front edge 13 of the top plate 11. The at least one supporting plate 142 and the at least one locking plate 143 are perpendicularly set on an end of the blocking plate 141 away from the top plate 11, and are spaced from each other at a first predetermined distance. In the embodiment, the at least one supporting plate 142 and the at least one locking plate 143 perpendicularly extend, staggered from the blocking plate 141 in opposite directions. In the embodiment, the locking portion 14 includes four supporting plates 142 and three locking plates 143.

Referring to FIG. 2 again, the lower cover 2 includes a bottom plate 21, at least one side wall 23, and a front panel 3 perpendicular with the bottom plate 21. In the embodiment, the front panel 3 is integrally formed with the lower cover 2. In other embodiments the front panel 3 may be detachably secured to the lower cover 2. The bottom plate 20 is substantially rectangular and corresponds to the top plate 11. The side wall 23 perpendicularly extends from an edge of the bottom plate 21 parallel to the front edge 13 of the top plate 11.

The front panel 3 is fixed to an edge of the bottom plate 21 opposite to the front edge 13 of the top plate 11. The front panel 3 includes a front plate 30, a first wall 31, and at least one limiting portion 32. The front plate 30 is substantially rectangular shaped. The first wall 31 perpendicularly extends from the edge of the front plate 30 away from the lower cover 2 and is parallel with the bottom plate 21.

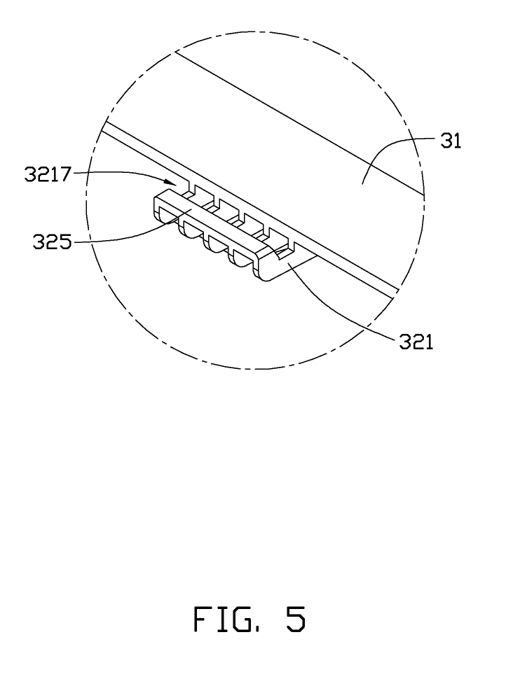

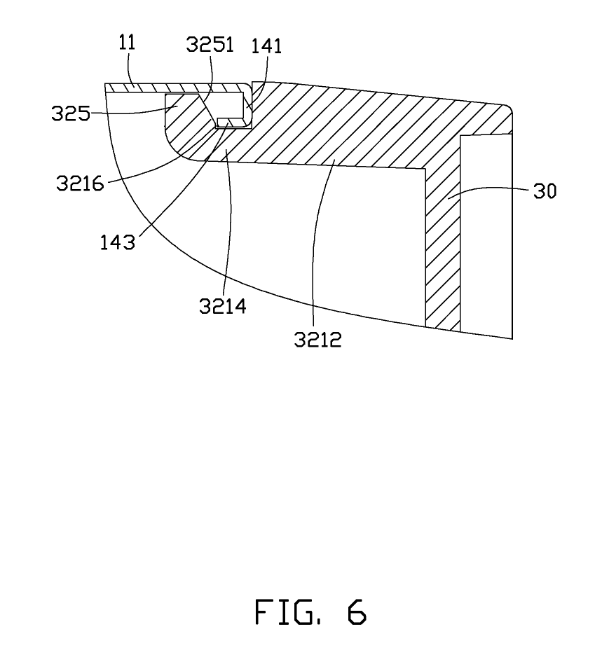

Referring to FIGS. 5-6, the limiting portion 32 corresponding to the locking plate 143 is perpendicularly set on the inner surface of the first wall 31 and corresponds to the locking plate 143. The limiting portion 32 partly protrudes from the front panel 3. In the embodiment, the front panel 3 includes three limiting portions 32. The limiting portion 32 includes a plurality of limiting plates 321 and a connecting portion 325 connecting the ends of the limiting plates 321. In the embodiment, the limiting plates 321 are integrally formed with the connecting portion 327, the connecting portion 325 is secured to the ends of the limiting plates 321 away from the first wall 31.

The limiting plates 321 are spaced from each other at a second predetermined distance. Each 321 includes a fixing portion 3212 fixed to an inner surface of the first wall 31 and a cantilever 3214 secured to the fixing portion 3212 and protruding out of the first wall 31. The end of the cantilever 3214 facing the bottom plate 21 is arced shaped. The cantilever 3214 defines a recess 3217. The recess 3217 is substantially U-shaped and is arranged adjacent to the first wall 31. The recesses 3217 cooperate with each other to define a clipping void (not labeled) for receiving and clipping the locking plate 143.

The connecting portion 325 connects with ends of the cantilevers 3214 away from the fixing portion 3212 and function as a rib for enhancing the stiffness of the limiting plates 321. The connecting portion 325 is substantially right-angled trapezoidal shaped and defines an inclined surface 3251. The inclined surface 3251 is used for guiding the locking plate 143 to be received in the recess 3217. A side portion of the recess 3217 connected with the inclined surface 3251 defines a blocking surface 3216 facing the fixing portion 3212.

Referring to FIG. 6, in assembly, the first wall 31 is disposed on the supporting plate 142 and the locking portion 14 is connected with the connecting portion 325. By moving the upper cover 1 towards the front panel 3, the locking plate 143 is received in the recess 3217 and abuts against the blocking surface 3216 via the inclined surface 3251. The blocking plate 141 is limited by the fixing portion 3212 for preventing the upper cover 1 from deforming and moving towards the front panel 3 in the horizontal direction. The locking plate 143 is limited by the cantilever 3214 for preventing the upper cover 1 from deforming and moving towards the lower cover 2 in the vertical direction. The locking plate 143 is limited by the blocking surface 3216 for preventing the upper cover 1 from deforming and moving away from the front panel 3 in the horizontal direction. The supporting plate 142 is limited by the first wall 31 for preventing the upper cover 1 from deforming and moving away from the lower cover 2 in the vertical direction. As a result, the upper cover 1 is steadily secured to the front panel 3.

While various exemplary and preferred embodiments have been described, it is to be understood that the disclosure is not limited thereto. To the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A housing of an electronic device, comprising:
an upper cover comprising a locking portion; and
a front panel secured to the upper cover and comprising a limiting portion corresponding to the locking portion;
wherein the locking portion comprising at least one locking plate; the limiting portion defines at least one recess corresponding to the at least one locking plate; the at least one locking plate is locked to the recess for preventing the upper cover from deforming and moving to separate from the front panel.

2. The housing of claim 1, wherein the upper cover further comprises a top plate; the locking portion further comprises a blocking plate perpendicularly extended from an edge of the top plate; the at least one locking plate is perpendicularly disposed on an end of the blocking plate.

3. The housing of claim 2, wherein the locking portion further comprises at least one supporting plate; the at least one supporting plate and the at least one locking plate perpendicularly extend from the blocking plate in opposite directions and are staggered with each other in a first predetermined distance.

4. The housing of claim 3, wherein the front panel comprises a front plate and a first wall perpendicularly set on an edge of the front plate; the at least one supporting plate is limited by the first wall for avoiding the upper cover moving away from the front panel in a vertical direction.

5. The housing of claim 3, wherein the limiting portion further comprises a plurality of limiting plates which are parallel and spaced from each other in a second predetermined distance; each of the limiting plates comprises a fixing portion and a cantilever secured to the fixing portion; the fixing portion perpendicularly fixes to an inner surface of the front panel; the recess is disposed on the cantilever.

6. The housing of claim 3, wherein the at least supporting plate is limited by the first wall for avoiding the upper cover moving towards the first wall in the vertical direction.

7. The housing of claim 5, wherein the cantilever is protruding out of the front panel.

8. The housing of claim 5, wherein the blocking plate is limited by the fixing portion for avoiding the upper cover moving towards the front panel in the horizontal direction.

9. The housing of claim 5, wherein the recess further comprises a blocking surface connected with the inclined surface; the locking plate is limited by the blocking surface for avoiding the upper cover moving away from the front panel in the horizontal direction.

10. The housing of claim 5, wherein the limiting portion further comprises a connecting portion; the connecting portion connects the end of the cantilevers for enhancing the stiffness of the limiting plates.

11. The housing of claim 10, wherein the cross-section of the connecting portion is substantially right-angled trapezoidal shaped.

12. The housing of claim 10, wherein the connecting portion comprises inclined surface abutting the blocking surface; the inclined surface facing the fixing portion is used for guiding the locking plate.

13. The housing of claim 1, wherein the recess is substantially U-shaped.
